(19) United States
(12) Patent Application Publication
(10) Pub. No.: US 2026/0212942 A1
(43) Pub. Date: Jul. 23, 2026

(54) MEMORY BUILT-IN SELF-TEST HAVING AN ADAPTABLE ACCESS PROTOCOL

(71) Applicant: Google LLC, Mountain View, CA (US)

(72) Inventors: Mayank Parasrampuria, Karnataka (IN); Samuel Tien-en Lee, Mountain View, CA (US)

(21) Appl. No.: 19/034,008

(22) Filed: Jan. 22, 2025

(51) Int. Cl. G11C 29/12; G11C 29/14

(52) U.S. Cl. CPC G11C 29/12015; G11C 29/1201; G11C 29/14

(57) ABSTRACT

A system on a chip can include a memory, a clock generating a clock signal, and an MBIST controller that issues read/write commands, according to the clock signal, to test the memory. The disclosed system on a chip further includes a clock-decoupling circuit positioned between the clock and the MBIST controller. The clock-decoupling circuit can be configured to decouple the clock from the MBIST controller after a read/write command is issued and until an operation complete signal is received from a multi-cycle access control module. The clock-decoupling circuit allows the MBIST controller to adapt to the multi-cycle access protocol run by the multi-cycle access control module without having to be programmed with its details.

### FIELD OF THE DISCLOSURE

The present disclosure relates to memory testing and more specifically to a memory built-in self-test.

### BACKGROUND

A system-on-a-chip (SOC) may include functional blocks of logic and circuitry referred to as cores. Each core may be thought of as a module configured to provide a particular function to the SOC. An SOC may include a core configured to test the memories of the SOC. This test may be run periodically (e.g., at startup) to verify that each memory cell in a memory is capable of a read/write operation. Accordingly, this test may be referred to as a memory built-in self-test (i.e., MBIST), and the logic and circuitry dedicated to this function may be referred to as an MBIST core.

### SUMMARY

An MBIST core is disclosed that can adapt to the timing required for reading and writing to a particular memory. The adaptation is achieved by decoupling a clock signal from an MBIST controller to pause the operation of the MBIST core while the memory can respond.

In some aspects, the techniques described herein relate to a system on a chip including: a memory; a clock configured to generate a clock signal; an MBIST controller configured to generate a read/write command to test the memory; a multi-cycle access control module coupled between the MBIST controller and the memory, the multi-cycle access control module configured to: receive the read/write command from the MBIST controller; transmit a clock pulse to the memory in response to the read/write command; and generate an operation-complete signal a number of clock cycles after the clock pulse; and a clock-decoupling circuit coupled between the clock and the MBIST controller, the clock-decoupling circuit configured to: decouple the clock from the MBIST controller based on the read/write command; and recouple the clock to the MBIST controller based on the operation-complete signal.

In some aspects, the techniques described herein relate to a method for performing a test of a memory, including: activating an MBIST controller programmed to execute a sequence of operations, the sequence of operations timed according to pulses of a clock signal received at the MBIST controller; transmitting a read/write command from the MBIST controller to the memory; decoupling the clock signal from the MBIST controller based on the read/write command to pause the sequence of operations; determining that a read/write operation, triggered by the read/write command, is complete; and recoupling the clock signal to the MBIST controller based on the read/write operation being complete to restart the sequence of operations.

In some aspects, the techniques described herein relate to a MBIST core for a system on a chip, the MBIST core including: an MBIST controller including a finite state machine configured to execute a sequence of operations according to clock pulses of a clock received at the MBIST controller; and a clock-decoupling circuit coupled to a clock terminal of the MBIST controller, the clock-decoupling circuit configured to: decouple the clock pulses of the clock from the clock terminal of the MBIST controller after a read/write command is transmitted to a memory; and recouple the clock pulses of the clock to the clock terminal of the MBIST controller after a read/write operation of the memory, which was triggered by the read/write command, is complete.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a system block diagram of a system on a chip according to a possible implementation of the present disclosure.

FIG. 2 is a system block diagram illustrating the access of a memory for a system on a chip according to a possible implementation of the present disclosure.

FIG. 3 is a system block diagram of a system on a chip according to a possible implementation of the present disclosure.

FIG. 4 is a stretch-logic circuit for a multi-access control module according to a possible implementation of the present disclosure.

FIG. 5 is a clock-decoupling circuit according to a possible implementation of the present disclosure.

FIG. 6 is a timing diagram of signals corresponding to a MBIST according to a possible implementation of the present disclosure.

FIG. 7 is a flowchart of a method for performing a test of a memory according to a possible implementation of the present disclosure.

The components in the drawings are not necessarily to scale relative to each other. Like reference numerals designate corresponding parts throughout the several views.

### DETAILED DESCRIPTION

An MBIST core for a system on a chip (SOC) may include an MBIST controller configured to transmit read and write commands to a memory in order to test its function. It may be desirable for the MBIST controller to be relatively small so that it does not occupy too much area of the SOC. It may also be desirable for the MBIST controller to carry out the test relatively fast so that the test does not overly impede normal operation. Accordingly, the MBIST controller may have fixed (i.e., hardwired, hardcoded) code for executing the memory test. One technical problem with this hardwired approach has to do with the access timing of the memory, which can change as a result of development or when trying to use the MBIST controller in a variety of systems. The MBIST controller can be rewritten and resynthesized in order to accommodate a change to the access timing, but this can be undesirable from a cost and time perspective, especially in the late-stages of a development process. Further, hardcoding all possible access timing scenarios may be undesirable from a size perspective. A technical solution is disclosed that can avoid hardcoding the access timing in the MBIST controller so that the MBIST core can be used in a variety of access timing scenarios. The technical solution may have the technical effect of reducing the cost and/or the time of a development process (e.g., for an SOC).

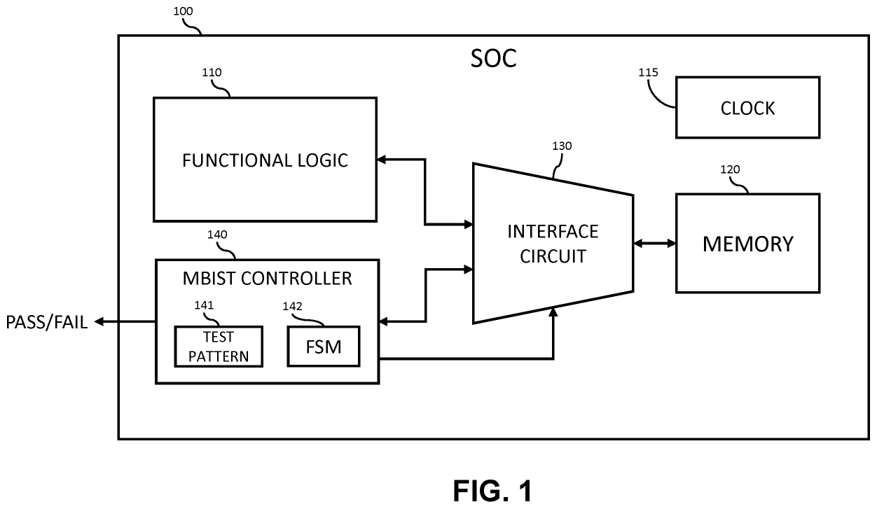

FIG. 1 is a system block diagram of an SOC according to a possible implementation of the present disclosure. The SOC 100 is an integrated circuit (IC) that includes digital circuitry (i.e. blocks, modules, cores) to carry out the computing components (e.g., processing, interface communication, etc.) necessary for an application.

In a possible implementation, the SOC 100 can be implemented as an application specific integrated circuit (ASIC) or a field programmable gate array (FPGA). Each core of the SOC 100 may include logic circuitry generated based on a process that includes synthesizing the circuitry based on a hardware description language, validating the circuitry, and placing and routing the circuitry. The cores may be communicatively coupled and collectively referred to as the functional logic 110 of the SOC 100. The SOC 100 further includes a system clock (i.e., clock 115), which can synchronize the timing of the (digital) circuitry of the cores.

The SOC 100 may include a memory 120. The memory 120 can be configured to function as a cache or as registers for the SOC. One memory is shown in FIG. 1 for the sake of brevity, but it should be understood that the disclosed techniques can be applied to multiple memories in an SOC. In a possible implementation, the memory 120 is a static random access memory (SRAM) including an array of SRAM cells arranged, and addressed, in rows and columns. In a possible implementation, the SRAM is part of a memory-in-pixel display.

Each SRAM cell may include a latch circuit configured to store a bit of information based on its state. Writing to an SRAM cell may be slowed by the time necessary to meet the threshold requirements for flipping the state of the latch circuit. A read/write operation can require transmitting signals to access a cell in the memory 120. The transmission of these signals can be slowed by parasitic capacitances associated with row and column conductors connecting the cells in the memory. Accordingly, a read/write operation of the memory 120 may be further slowed by these parasitic effects.

A read operation spans a period between the transmission of a read command and the reception of data corresponding to the read command, while a write operation spans a period between the transmission of a write command and the storage of data corresponding to the write command. As a result of the slowing effects described above, the period of the write operation and/or the read operation can span multiple cycles of the clock 115 (i.e., multi-cycle access).

Faults in one or more cells of the memory may result in a malfunction of the SOC. A fault in the memory 120 may result in a memory cell (or memory cells) that cannot be written to or read from. For example, a faulty SRAM cell may be referred to as a stuck bit when it cannot be changed from one binary state to another during a write operation. The memory 120 may have faults in a cell or a group of cells. The faults may be temporary or permanent and may result from manufacturing defects (e.g., faulty transistors), electromagnetic interference, or use. A memory cell may be tested by writing and reading data according to a known value or sequence. Errors in this test can occur when the write operation(s) and/or the read operation(s) are performed faster than the memory cell can respond. For example, a bit written to the memory cell at a first clock cycle and then read at a second clock cycle, immediately following the first clock cycle (i.e., single-cycle access), may be inaccurate if the memory requires multiple clock cycles for the read and write operations to complete.

As shown in FIG. 1, SOC 100 includes an MBIST controller 140 configured to test the memory 120 for faults. The MBIST controller 140 may perform the test as part of a factory validation or may perform the test during use, such as each time the SOC is started (i.e., at startup). To perform the test, the MBIST controller 140 may transmit a signal to a test wrapper and interface (i.e., interface circuit 130), which can provide the MBIST controller 140 access and control of the memory 120 in response. In other words, the interface circuit 130 may be configured to multiplex access between the functional logic 110 and the MBIST controller 140.

The MBIST controller 140 may include fixed (i.e., hard coded) software instructions to perform read/write operations according to a test protocol. The MBIST controller 140 may be configured to compare data read from the memory 120 to a test pattern 141 stored (e.g., in the MBIST controller 140) and output a pass signal or a fail signal based on a comparison. In a possible implementation, the MBIST controller 140 may include a finite state machine 142 (FSM) configured to execute a sequence of operations according to clock pulses (i.e., clock cycles) of the clock 115. For example, the finite state machine 142 may issue a write command and a read command on subsequent clock cycles of a clock received at the MBIST controller 140.

Accessing the memory 120 with a multi-cycle access protocol may include adapting (i.e., modifying) the clock signal received at the memory 120 so that the periods for write operations and read operations are greater than a clock period of the clock signal (CLK). This adaptation may be referred to as clock stretching. Clock stretching may be implemented by dividing the clock, which slows the clock frequency while maintaining the duty-cycle of the clock pulses. Clock stretching may also be implemented by generating a punch-through clock signal (i.e., punch-through clock). The punch-through clock includes a series of clock pulses separated by a punch-through period that is larger than a clock period by a number of clock pulses (i.e., clock cycles).

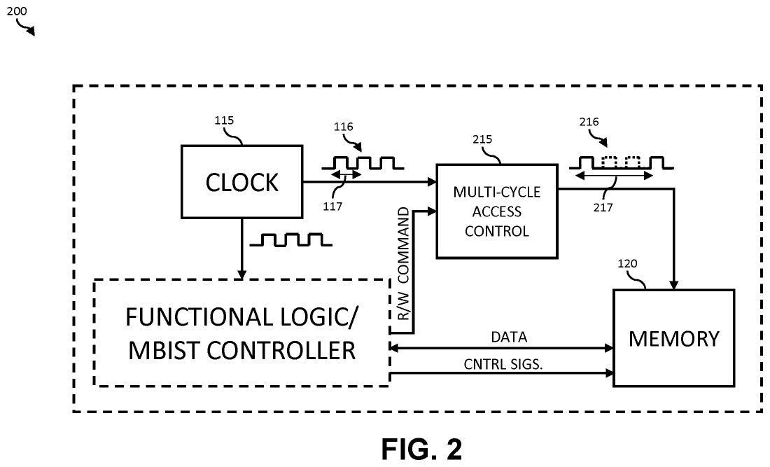

FIG. 2 is a system block diagram illustrating a portion of the system on a chip related to the access of a memory 120 according to a possible implementation of the present disclosure. As shown, the clock 115 (i.e., system clock) may transmit a clock signal 116 (i.e., high frequency clock signal) to the functional logic 110. The clock signal 116 includes a series of clock pulses separated by a clock period 117. The frequency of the clock signal 116 may be much higher (e.g., 10 times higher) than the memory 120 is configured to operate. Accordingly, the memory 120 may be clocked by a punch-through clock 216 that cycles at a lower frequency suitable for the read/write operations of the memory 120.

The system 200 further includes a multi-cycle access control module 215 configured to generate the punch-through clock 216 based on the clock signal 116 received from the clock 115. The punch-through clock 216 includes a series of clock pulses separated by a punch-through period 217 that can be larger than a clock period 117 by a number of clock pulses. Accordingly, the multi-cycle access control module 215 may be configured to gate the clock signal 116 so that one punch-through clock pulse is transmitted every N^{th} pulse of the clock signal 116. The number of clock pulses of the clock signal 116 skipped between the clock pulses of the punch-through clock 216 may depend on the operation of the memory. For example, a read command may trigger a first multi-cycle protocol while a write command may trigger a second multi-cycle protocol.

As shown in FIG. 2, a read/write command (R/W command) generated by functional logic or the MBIST controller may trigger the multi-cycle access control module 215 generate a punch-through clock to clock the memory according to a multi-access protocol stored in the multi-cycle access control module 215. The MBIST controller may not have knowledge of the multicycle access protocol stored in the multi-cycle access control module 215 and may not have the ability to communicate with the functional logic to change it. This can create test problems if the MBIST controller is configured to operate according to a multi-cycle access protocol that is different from the one used by (e.g., stored in) the multi-cycle access control module 215. The disclosed system on a chip includes circuitry to help the MBIST controller adapt to whatever multicycle access protocol is in use.

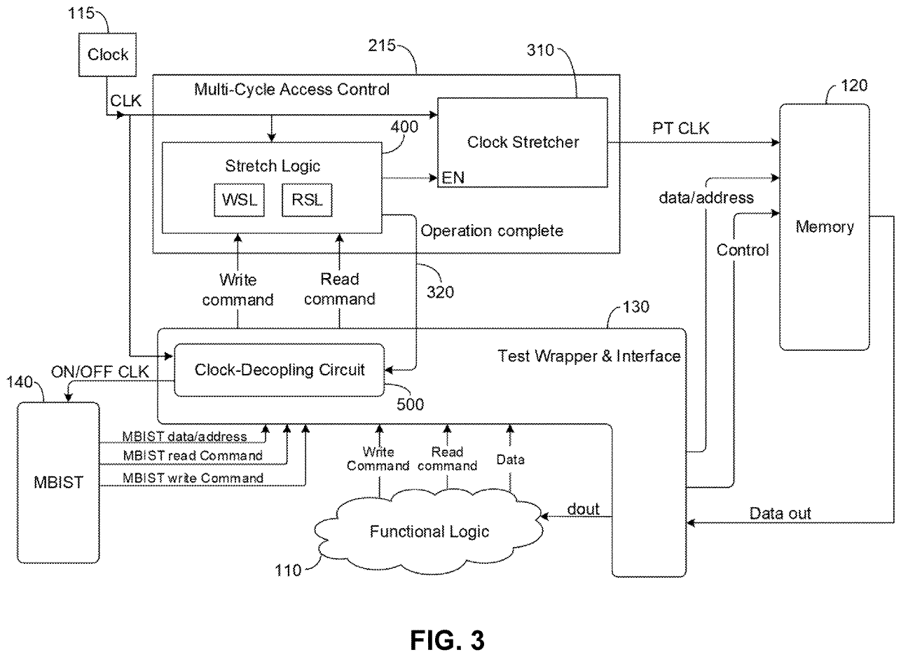

FIG. 3 is a system block diagram of a system on a chip (i.e., system) according to a possible implementation of the present disclosure. The system includes a clock 115 configured to generate a clock signal (CLK). The system includes a multi-cycle access control module 215 configured to output a punch-through clock signal (PT CLK) based on the clock signal (CLK) at an input.

The punch-through clock signal (PT CLK) may be a gated version of the clock signal (CLK). Accordingly, the multi-cycle access control module 215 can include a clock stretcher circuit (i.e., clock stretcher 310). The clock stretcher 310 may be configured to gate the clock signal (CLK) according to a specified number of clock pulses. The clock stretcher 310 may include a gate (e.g., switch) that blocks the clock signal (CLK) based on an enable signal (EN). For example, the clock stretcher 310 can be configured to pass a pulse from the clock signal (CLK) when the enable signal (EN) is at a first level (e.g., HIGH) and configured to block pulses from the clock signal (CLK) when the enable signal (EN) is at a second level (e.g., LOW).

The enable signal (EN) may be generated by a stretch logic circuit (i.e., stretch logic 400). After a read/write command is received, the stretch logic 400 may be configured to detect a stretch parameter and to toggle the enable signal (EN) after the stretch parameter is detected.

The stretch parameter, which may be stored in a register (or registers) of the stretch logic 400, can correspond to a number of clock pulses (i.e., clock cycles) to skip (i.e., wait) after receiving a read/write command. For example, the stretch parameter may include a write stretch-limit (WSL) corresponding to the number of clock pulses to skip after receiving a write command, and the stretch logic 400 may further include a read stretch-limit (RSL) corresponding to the number of clock pulses to skip after receiving a read command. The write stretch-limit (WSL) and the read stretch-limit (RSL) may correspond to the multi-cycle access protocol. In a possible implementation, the write stretch-limit (WSL) equals the read stretch-limit (RSL).

The system also includes an interface circuit 130 (i.e., test wrapper and interface) configured to multiplex (e.g., switch) access to the memory 120 between an MBIST controller 140 and the functional logic 110. The interface circuit 130 may include a clock-decoupling circuit 500. The clock-decoupling circuit 500 is connected between the clock 115 and the MBIST controller 140. An output of the clock-decoupling circuit 500 can be connected to a clock terminal of the MBIST controller 140 to control its operation.

Based on a state of the clock-decoupling circuit 500, the clock-decoupling circuit 500 can be configured to decouple the clock signal (CLK) from the MBIST controller 140 or couple the clock signal (CLK) to the MBIST controller 140. In other words, the clock terminal of the MBIST controller may receive clock pulses from the clock 115 while the clock-decoupling circuit 500 is in a first state (i.e., coupled) or may not receive clock pulses from the clock 115 while the clock-decoupling circuit 500 is in a second state (i.e., decoupled).

Decoupling the MBIST controller 140 from the clock 115 can deactivate the MBIST controller 140 so that its execution of the test protocol is paused. The timing of the decoupling may be made to correspond to the stretch parameter (e.g., RSL, WSL) so that the MBIST controller 140 executes the test protocol according to the multi-cycle access timing of the memory 120 without the MBIST controller 140 having access to, or knowledge of, the stretch parameter (e.g., RSL, WSL).

The clock-decoupling circuit 500 may receive a read/write command from the MBIST controller 140. The read/write command may trigger the clock-decoupling circuit 500 to block the clock signal (CLK) from reaching the MBIST controller 140. The clock-decoupling circuit 500 can be configured to recouple (i.e., reconnect, pass) the clock signal to the MBIST controller 140 after receiving an operation-complete signal 320 from the stretch logic 400. In other words, the clock-decoupling circuit 500 can be configured to decouple the clock signal from the MBIST controller 140 based on a read/write command in order to pause a sequence of test operations executed by the MBIST controller 140 at the start of a read/write operation. The clock-decoupling circuit 500 can be further configured to couple (i.e., recouple) the clock signal to the MBIST controller 140 based on the operation-complete signal 320 in order to restart the sequence of test operations executed by the MBIST controller 140 at the conclusion of the read/write operation (e.g., after the read/write operation).

The operation-complete signal (i.e. done signal) may indicate that either the write operation is complete (i.e., write done) or the read operation is complete (i.e., read done). One operation-complete signal may be used when the read stretch parameter (RSL) equals the write stretch parameters (WSL). In an alternate implementation, the stretch logic 400 may generate a write-operation-complete signal (i.e. write-done signal) when a write operation is complete and may generate a read-operation-complete signal (i.e., read-done signal) when a read operation is complete. In any case, the stretch logic 400 includes circuitry to output an operation-complete signal 320 (or signals) to the clock-decoupling circuit 500.

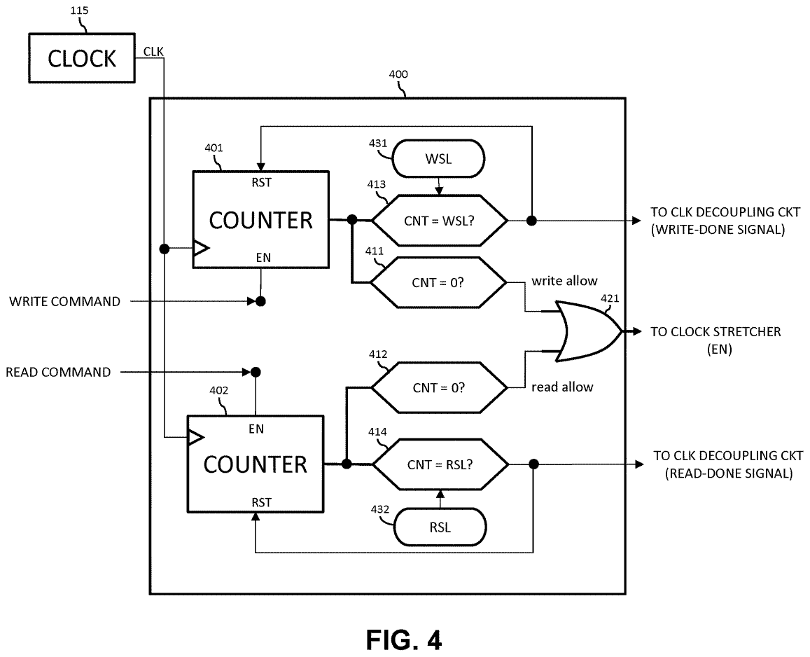

FIG. 4 is a stretch-logic circuit for a multi-access control module according to a possible implementation of the present disclosure. The stretch logic 400 is configured to receive a clock signal (CLK) from a clock 115. The stretch logic 400 is further configured to receive a write command or a read command from the MBIST controller 140, via the interface circuit 130.

In a possible implementation, the stretch logic 400 can include a first counter 401 and a second counter 402. The first counter 401 can be enabled by a write command to start counting clock pulses (i.e., clock cycles) of the clock signal (CLK) and the second counter 402 can be enabled by a read command to start counting clock pulses (i.e., clock cycles) of the clock signal (CLK).

In a possible implementation, the output of the first counter 401 is transmitted to a first comparator 411, which can activate a write-allow signal to enable (i.e., start) a write operation (for the memory) when the count (CNT) of the first counter 401 is zero. In a possible implementation the output of the second counter 402 is transmitted to a second comparator 412, which can activate a read-allow signal to enable (i.e., start) a read operation (for the memory) when the count (CNT) of the second counter 402 is zero. In a possible implementation, the stretch logic 400 includes an OR gate 421 configured to output an enable signal (EN) to the clock stretcher 310 when either the write-allow signal or the read-allow signal is active. The enable signal (EN) may correspond to a pulse of the punch-through clock.

In a possible implementation, the output of the first counter 401 is transmitted to a third comparator 413, which can activate a write-done signal when the count of the first counter 401 reaches a write-stretch limit (WSL). The write-stretch limit (WSL) may be recalled by the third comparator 413 from a first memory 431 (i.e., second register) and can represent the number of clock pulses of the clock signal (CLK) to skip between clock pulses of the punch-through clock signal (PT CLK). The write-done signal may be transmitted to the clock-decoupling circuit 500. In a possible implementation, the write-done signal may also be fed back to the first counter 401 to reset the first counter 401 (e.g., to zero).

In a possible implementation, the output of the second counter 402 is transmitted to a fourth comparator 414, which can activate a read-done signal when the count of the second counter 402 reaches a read-stretch limit (RSL). The read-stretch limit (RSL) may be recalled by the fourth comparator 414 from a second memory 432 (i.e., second register) and can represent the number of clock pulses of the clock signal (CLK) to skip between clock pulses of the punch-through clock signal (PT CLK). The read-done signal may be transmitted to the clock-decoupling circuit 500. In a possible implementation, the read-done signal may also be fed back to the second counter 402 to reset the second counter 402 (e.g., to zero).

In a possible implementation, the write-done signal and the read-done signal may be coupled to a logic gate (e.g., OR gate) which can generate an operation-complete signal after either the write-done signal or the read-done signal is activated. For example, the operation-complete signal may be activated (e.g., generated) a number of clock cycles after the initial clock pulse (i.e. CNT=0) generated by the read/write command.

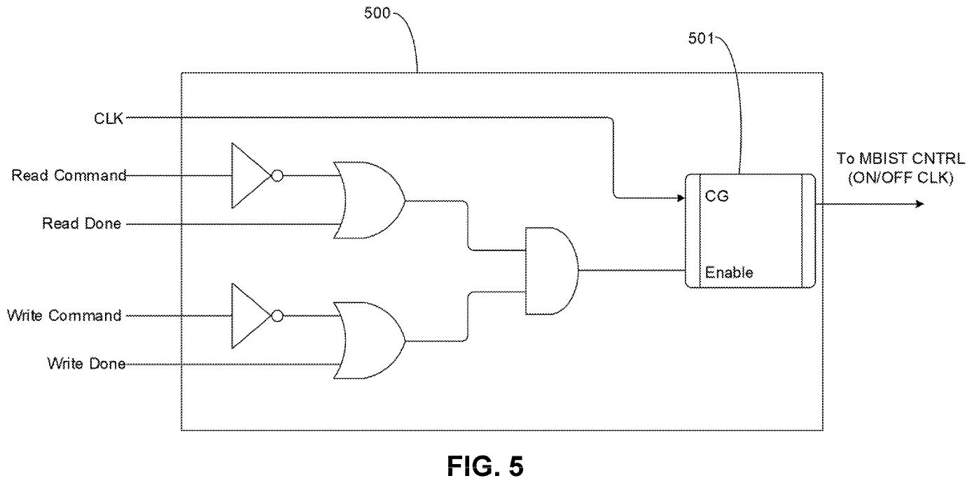

FIG. 5 is a clock-decoupling circuit according to a possible implementation of the present disclosure. The clock-decoupling circuit 500 is configured to output a coupled/decoupled (i.e., gated) clock signal (ON/OFF CLK) to the MBIST controller 140. In a possible implementation, the coupled/decoupled clock signal (ON/OFF CLK) is a version of the clock signal (CLK) that is modulated (i.e. toggled) ON/OFF by an enable signal generated by logic of the clock-decoupling circuit 500. Accordingly, the clock-decoupling circuit 500 can include a clock gate 501 (e.g., switch) configured to pass or block the clock signal (CLK) based on the state of the enable signal. In a possible implementation, when the enable signal is HIGH the clock signal is gated (i.e. decoupled) and when the enable signal is LOW the clock signal is not gated (i.e., passed).

The clock signal may be decoupled (i.e., zero, inactive) at the start of a read operation based on a read command and recoupled (i.e., non-zero, active) at (or after) the end of the read operation based on a read done signal. Further, the clock signal may be decoupled (i.e., zero, inactive) at the start of a write operation based on a write command and recoupled (i.e., non-zero, active) at (or after) the end of the write operation based on a write done signal. As shown by the logic, the ON/OFF clock signal may be non-zero (i) when the read command and the write command are not present (i.e., inactive) or (ii) when the read operation and the write operation are complete (i.e., not active). Otherwise, the clock signal is decoupled from the MBIST controller. In other words, the clock may be coupled to the MBIST controller during periods between read and write commands while no read or write operation is active.

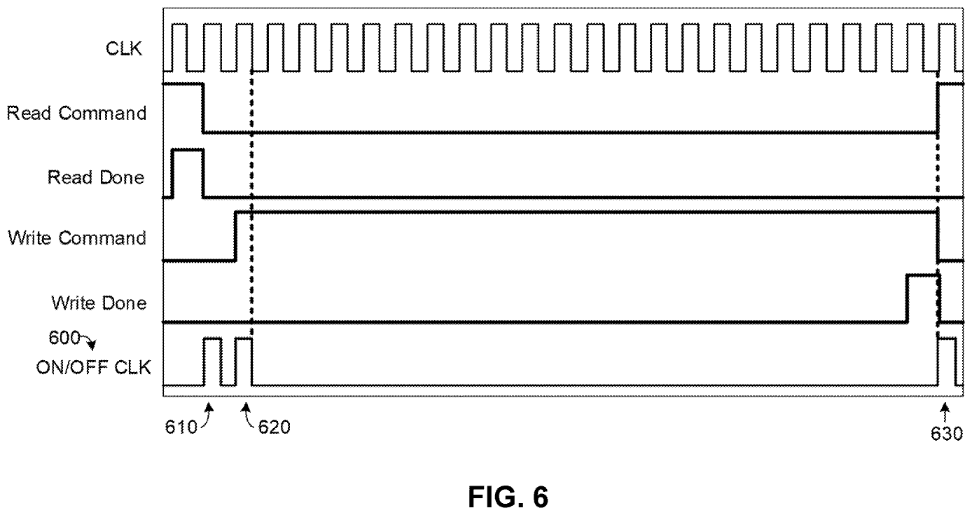

FIG. 6 is a timing diagram of signals corresponding to a MBIST according to a possible implementation of the present disclosure. The signals are active when they are at a HIGH level and inactive when they are at a low level. The ON/OFF clock signal 600 is the clock received by the MBIST controller 140. As shown, the MBIST controller 140 may receive a first clock pulse 610 after a read operation is complete (i.e., after the read command goes inactive) and before a write operation has begun (i.e., before a write command becomes active). The MBIST controller transmits a write command at a second clock pulse 620 to start a write operation. After the write operation is started (i.e., after the second clock pulse 620), the ON/OFF clock signal 600 becomes inactive. The inactive clock signal pauses the operation of the MBIST controller so that no (new) commands are issued by the MBIST controller 140 while the ON/OFF clock signal is inactive.

As shown in FIG. 6, a write-done signal (generated by the stretch logic 400) can re-activate (i.e., couple, recouple) the ON/OFF clock signal so that a third clock pulse 630 is received at the MBIST controller 140. The third clock pulse 630 can restart the operations of the MBIST controller 140 (e.g., to issue a new command). The number of pulses between the second clock pulse 620 and the third clock pulse 630 may correspond to the write-stretch limit (WSL) but this limit is not programmed in the MBIST controller 140. Accordingly, the MBIST controller 140 can operate with different write-stretch limits (e.g., any write-stretch limit) used by the stretch logic 400 without any additional programming.

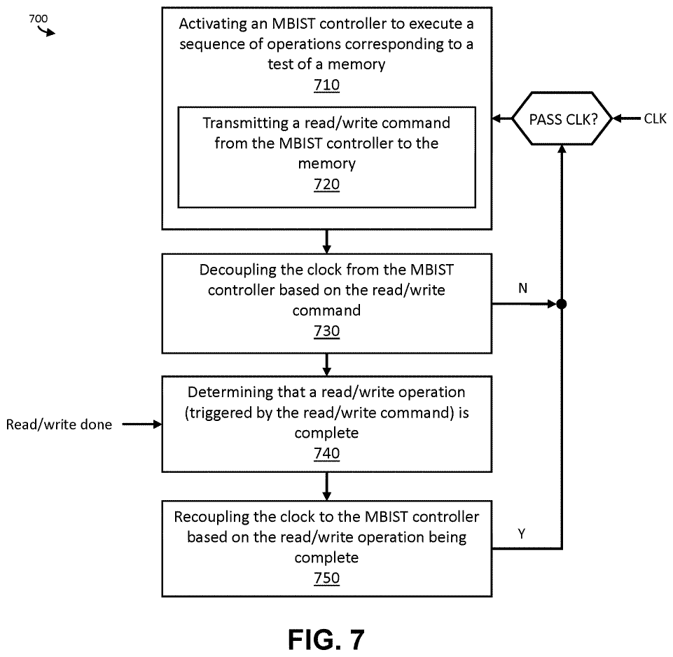

FIG. 7 is a flowchart of a method for performing a test of a memory according to a possible implementation of the present disclosure. The method 700 includes activating 710 an MBIST controller to execute a sequence of operations according to cycles of a clock signal (CLK). The sequence of operations includes read commands and write commands corresponding to a test of a memory (e.g., SRAM). The method 700 further includes configuring the MBIST controller to transmit 720 a read command or a write command to the memory. The read command or the write command (i.e., read/write command) can cause the decoupling 730 of the clock from the MBIST controller. In other words, the clock signal (CLK) may be blocked from reaching the MBIST controller until the read/write operation, which was triggered by the read/write command, is complete. Accordingly, the method 700 can include determining 740 that the read/write operation is complete, and recoupling 750 the clock to the MBIST controller based on the determination. The read/write operation can be determined as being complete based on a read/write done signal. After the clock is recoupled, the MBIST controller may be activated 710 to continue executing the sequence of operations corresponding to the test of the memory.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

What is claimed is:

1. A system on a chip comprising:
a memory;
a clock configured to generate a clock signal;
an MBIST controller configured to generate a read/write command to test the memory;
a multi-cycle access control module coupled between the MBIST controller and the memory, the multi-cycle access control module configured to:
receive the read/write command from the MBIST controller;
transmit a clock pulse to the memory in response to the read/write command; and
generate an operation-complete signal a number of clock cycles after the clock pulse; and
a clock-decoupling circuit coupled between the clock and the MBIST controller, the clock-decoupling circuit configured to:
decouple the clock from the MBIST controller based on the read/write command; and
recouple the clock to the MBIST controller based on the operation-complete signal.

2. The system on the chip according to claim 1, wherein the MBIST controller is a finite state machine.

3. The system on the chip according to claim 2, wherein the finite state machine is configured to transmit write commands and read commands according to a test protocol based on a test pattern.

4. The system on the chip according to claim 1, wherein the multi-cycle access control module is configured to output a punch-through clock to the memory, the punch-through clock having a period that is greater than the clock.

5. The system on the chip according to claim 4, wherein the period of the punch-through clock is based on a stretch parameter stored in a register of the multi-cycle access control module.

6. The system on the chip according to claim 1, wherein the clock-decoupling circuit is configured to output an ON/OFF clock to the MBIST controller, the ON/OFF clock being a modulated version of the clock signal.

7. The system on the chip according to claim 1, wherein the memory is a static random access memory (SRAM).

8. The system on the chip according to claim 7, wherein the SRAM is part of a memory-in-pixel display.

9. The system on the chip according to claim 1, further comprising a test wrapper interface circuit configured to multiplex access to the memory to the MBIST controller and a functional logic.

10. The system on the chip according to claim 1, wherein the operation-complete signal is a write-done signal or a read-done signal.

11. The system on the chip according to claim 10, where in the multi-cycle access control module includes a stretch-logic circuit including:
a write counter configured to:
output a write-allow signal when a first count is zero; and
output the write-done signal when the first count has reached a write-stretch limit; and
a read counter configured to:
output a read-allow signal when a second count is zero; and
output the read-done signal when the second count has reached a read-stretch limit.

12. The system on the chip according to claim 10, wherein the clock-decoupling circuit includes:
a clock gate; and
a logic gate configured to control the clock gate based on states of the write-done signal and the read-done signal.

13. A method for performing a test of a memory, comprising:
activating an MBIST controller programmed to execute a sequence of operations, the sequence of operations timed according to pulses of a clock signal received at the MBIST controller;
transmitting a read/write command from the MBIST controller to the memory;
decoupling the clock signal from the MBIST controller based on the read/write command to pause the sequence of operations;
determining that a read/write operation, triggered by the read/write command, is complete; and
recoupling the clock signal to the MBIST controller based on the read/write operation being complete to restart the sequence of operations.

14. The method for performing the test of the memory according to claim 13, wherein the read/write command is a write command and determining that the write command is complete includes:
generating a write-allow signal based on the write command, the write-allow signal corresponding to a start of a write operation;
enabling a write counter to count clock cycles of the clock signal after the start of the write operation; and
generating a write-done signal after the write counter reaches a write stretch limit, the write-done signal configuring a clock-decoupling circuit to recouple the clock signal to the MBIST controller.

15. The method for performing the test of the memory according to claim 13, wherein the read/write command is a read command and determining that the read command is complete includes:
generating a read-allow signal based on the read command, the read-allow signal corresponding to a start of a read operation;
enabling a read counter to count clock cycles of the clock signal after the start of the read operation; and
generating a read-done signal after the read counter reaches a read stretch limit, the read-done signal configuring a clock-decoupling circuit to couple the clock signal to the MBIST controller.

16. The method for performing the test of the memory according to claim 13, wherein recoupling the clock signal to the MBIST controller occurs after a read/write period used by the memory to execute the read/write operation.

17. The method for performing the test of the memory according to claim 16, wherein the read/write period is longer than a clock period of the clock signal.

18. The method for performing the test of the memory according to claim 16, wherein the read/write period is not included in programming of the MBIST controller.

19. A MBIST core for a system on a chip, the MBIST core comprising:
an MBIST controller including a finite state machine configured to execute a sequence of operations according to clock pulses of a clock received at the MBIST controller; and
a clock-decoupling circuit coupled to a clock terminal of the MBIST controller, the clock-decoupling circuit configured to:
decouple the clock pulses of the clock from the clock terminal of the MBIST controller after a read/write command is transmitted to a memory; and
recouple the clock pulses of the clock to the clock terminal of the MBIST controller after a read/write operation of the memory, which was triggered by the read/write command, is complete.

20. The MBIST core for the system on the chip according to claim 19, further including a stretch logic circuit configured to:
generate an enable signal based on the read/write command, the enable signal corresponding to a start of the read/write operation;
enabling a counter to count the clock pulses of the clock after the start of the read/write operation; and
generating an operation-complete signal after the counter reaches a stretch limit, the operation-complete signal configuring the clock-decoupling circuit to recouple the clock pulses of the clock to the clock terminal of the MBIST controller.
